(19) United States
(12) Patent Application Publication
(10) Pub. No.: US 2026/0239782 A1
(43) Pub. Date: Aug. 13, 2026

(54) MICRO-DISPLAY CHIP STRUCTURE AND PREPARING METHOD THEREFOR

(71) Applicant: Raysolve Optoelectronics (Suzhou) Company Limited, Suzhou (CN)

(72) Inventors: Nao ZHANG, Suzhou (CN); Xu ZHANG, Suzhou (CN); Wing Cheung CHONG, Suzhou (CN); Hongtu ZENG, Suzhou (CN); Ziyuan LU, Suzhou (CN)

(73) Assignee: Raysolve Optoelectronics (Suzhou) Company Limited, Suzhou (CN)

(21) Appl. No.: 19/645,040

(22) Filed: Apr. 10, 2026

Related U.S. Application Data
(63) Continuation of application No. PCT/CN2024/123666, filed on Oct. 9, 2024.

(30) Foreign Application Priority Data
Oct. 12, 2023 (CN) 202311322124.7

(51) Int. Cl. H10H 20/851; H10H 20/01; H10H 20/841; H10H 20/855; H10H 20/856; H10H 29/01; H10H 29/85

(52) U.S. Cl. CPC H10H 20/8514; H10H 20/034; H10H 20/0361; H10H 20/0363; H10H 20/841; H10H 20/855; H10H 20/856; H10H 29/0365; H10H 29/8581

(57) ABSTRACT

A micro-display chip structure includes: a driving circuit substrate; a plurality of light-emitting units disposed on the driving circuit substrate and spaced apart from each other; a color conversion layer disposed on the plurality of light-emitting units, the color conversion layer at least including first wavelength conversion units; a supporting frame including a plurality of supporting units, each supporting unit of the plurality of supporting units being disposed corresponding to each light-emitting unit of the plurality of light-emitting units, and the supporting unit at least covering a sidewall of the light-emitting unit; and a first reflective layer, at least covering a sidewall of the supporting unit. Embodiments of the present disclosure may simplify a preparation process of the micro-display chip structure and reduce a risk of damage to the light-emitting unit caused by partial etching processes during the preparation process of the micro-display chip structure.

### CROSS-REFERENCE TO RELATED APPLICATIONS

The present application is a continuation application of International Application No. PCT/CN2024/123666, filed on October 9, 2024, which claims priority to Chinese Patent Application No. 202311322124.7, filed on October 12, 2023. All of the aforementioned applications are incorporated herein by reference in their entireties.

### TECHNICAL FIELD

The present disclosure relates to the field of micro-display technologies, and in particular, to a micro-display chip structure and a preparing method for the micro-display chip structure.

### BACKGROUND

In recent years, display industry has experienced rapid development, particularly in China, where the display industry has undergone earth-shaking changes. Examples include a flexible Liquid Crystal Display (LCD), a Mini Light-Emitting Diode (Mini-LED), a Micro Light-Emitting Diode (Micro-LED), and the like.

Micro-LED display technology is a display technology that miniaturizes and arrays traditional LED structures, and uses a Complementary Metal Oxide Semiconductor (CMOS) integrated circuit process to fabricate a driving chip, thereby enabling control and individual driving of each pixel. The Micro-LED is widely promoted by many companies due to its advantages such as wide color gamut, high contrast ratio, fast response speed, high resolution, and long lifespan, and is also regarded as the most promising next-generation new display technology.

Existing preparing methods for display chip structures have technical problems such as a complex process and a tendency to damage light-emitting units in the display chip structures.

### SUMMARY

In view of this, the present disclosure provides a micro-display chip structure and a preparing method therefor, solving the technical problems in related art in which a preparation process of micro-display chip structures is complex and causes damage to the light-emitting units.

According to an aspect of the present disclosure, the present disclosure provides a micro-display chip structure, which includes: a driving circuit substrate; a plurality of light-emitting units disposed on the driving circuit substrate and spaced apart from each other, the plurality of light-emitting units at least including first light-emitting units, and the first light-emitting units being configured to emit light of a first color; a color conversion layer disposed on the plurality of light-emitting units, the color conversion layer at least including first wavelength conversion units, the first wavelength conversion units being disposed corresponding to the first light-emitting units, and the first wavelength conversion units being configured to convert the light of the first color emitted by the first light-emitting units into light of a second color; a supporting frame including a plurality of supporting units, each supporting unit of the plurality of supporting units being disposed corresponding to each light-emitting unit of the plurality of light-emitting units, and the supporting unit at least covering a sidewall of the light-emitting unit; and a first reflective layer, at least covering a sidewall of the supporting unit.

In an embodiment of the present disclosure, the supporting unit has an inclined sidewall.

In an embodiment of the present disclosure, the micro-display chip structure further includes: a planarization layer filling a gap between two adjacent supporting units of the plurality of supporting units to form a flat top surface.

In an embodiment of the present disclosure, the plurality of light-emitting units further include second light-emitting units, light emitted by the second light-emitting units and light emitted by the first light-emitting units are of the same color; and the color conversion layer further includes second wavelength conversion units, the second wavelength conversion units are disposed corresponding to the second light-emitting units, and the second wavelength conversion units are configured to convert light of the first color emitted by the second light-emitting units into light of a third color.

In an embodiment of the present disclosure, the plurality of light-emitting units further include third light-emitting units, light emitted by the third light-emitting units and the light emitted by the first light-emitting units are of the same color; the color conversion layer further includes light-transmitting structures, the light-transmitting structures are disposed corresponding to the third light-emitting units; and the light-transmitting structures are configured to transmit light of the first color emitted by the third light-emitting units.

In an embodiment of the present disclosure, the micro-display chip structure further includes: a first transmissive-reflective layer disposed between the plurality of light-emitting units and the color conversion layer, where the first transmissive-reflective layer is configured to transmit the light of the first color and reflect light of other color.

In an embodiment of the present disclosure, the micro-display chip structure further includes: a thermal insulation layer disposed between the plurality of light-emitting units and the color conversion layer, where the thermal insulation layer is configured to at least transmit the light of the first color.

In an embodiment of the present disclosure, the first transmissive-reflective layer includes: a plurality of transmissive-reflective units, where the plurality of transmissive-reflective units are respectively disposed corresponding to the plurality of light-emitting units; and a light-blocking structure, disposed between two adjacent transmissive-reflective units among the plurality of transmissive-reflective units; where each transmissive-reflective unit of the plurality of transmissive-reflective units covers a light-emitting surface of a light-emitting unit disposed corresponding to the transmissive-reflective unit.

In an embodiment of the present disclosure, the micro-display chip structure further includes: a second transmissive-reflective layer disposed above the color conversion layer, where the second transmissive-reflective layer is configured to transmit light of other color and reflect the light of the first color.

In an embodiment of the present disclosure, the micro-display chip structure further includes: a plurality of microlenses disposed above the color conversion layer, where the plurality of microlenses are disposed corresponding to the plurality of light-emitting units.

As a second aspect of the present disclosure, the present disclosure further provides a preparing method for a micro-display chip structure, which includes: forming a plurality of light-emitting units on a side of a driving circuit substrate, the plurality of light-emitting units at least including first light-emitting units, and the first light-emitting units being configured to emit light of a first color under driving of the driving circuit substrate; forming a supporting frame on the driving circuit substrate, the supporting frame including a plurality of supporting units, each supporting unit of the plurality of supporting units being disposed corresponding to each light-emitting unit of the plurality of light-emitting units, and the supporting unit at least covering a sidewall of the light-emitting unit; forming a first reflective layer on a sidewall of the supporting unit; and forming a color conversion layer above the plurality of light-emitting units, the color conversion layer at least including first wavelength conversion units, the first wavelength conversion units being disposed corresponding to the first light-emitting units, and the first wavelength conversion units being configured to convert the light of the first color emitted by the first light-emitting units into light of a second color.

In an embodiment of the present disclosure, the forming the first reflective layer on the sidewall of the supporting unit includes: forming a reflective layer on the light-emitting unit, the reflective layer covering the sidewall and an upper surface of the supporting unit, a light-emitting surface of the light-emitting unit, and a gap between two adjacent light-emitting units of the plurality of light-emitting units; and removing, by an etching process, the reflective layer on the upper surface of the supporting unit, the reflective layer on the light-emitting surface of the light-emitting unit, and the reflective layer in the gap between the two adjacent light-emitting units, and at least retaining the reflective layer located on the sidewall of the supporting unit; where the first reflective layer is the reflective layer at least located on the sidewall of the supporting unit.

In an embodiment of the present disclosure, after forming the first reflective layer on the sidewall of the supporting unit and before forming the color conversion layer above the plurality of light-emitting units, the preparing method further includes: forming a planarization layer on the driving circuit substrate, the planarization layer filling a gap between two adjacent supporting units of the plurality of supporting units to form a flat top surface; where the forming the color conversion layer above the plurality of light-emitting units includes: forming the color conversion layer above the planarization layer.

In an embodiment of the present disclosure, after forming the planarization layer on the driving circuit substrate and before forming the color conversion layer above the plurality of light-emitting units, the preparing method further includes: forming a first transmissive-reflective layer on the planarization layer, where the first transmissive-reflective layer is configured to transmit the light of the first color and reflect light of other color.

In an embodiment of the present disclosure, the forming the first transmissive-reflective layer on the planarization layer includes: forming the first transmissive-reflective layer on the planarization layer through an exposure and development process, where the first transmissive-reflective layer includes a plurality of transmissive-reflective units, and the plurality of transmissive-reflective units are respectively disposed corresponding to the plurality of light-emitting units; and forming a light-blocking structure, disposed between two adjacent transmissive-reflective units of the plurality of transmissive-reflective units; where each transmissive-reflective unit of the plurality of transmissive-reflective units covers a light-emitting surface of a light-emitting unit disposed corresponding to the transmissive-reflective unit.

In an embodiment of the present disclosure, before forming the color conversion layer above the plurality of light-emitting units, the preparing method further includes: forming a thermal insulation layer on the plurality of light-emitting units; where the forming the color conversion layer above the plurality of light-emitting units includes: forming the color conversion layer above the thermal insulation layer.

In an embodiment of the present disclosure, the forming the plurality of light-emitting units on the side of the driving circuit substrate includes: forming the first light-emitting units and second light-emitting units on the side of the driving circuit substrate, the first light-emitting units and the second light-emitting units being configured to emit the light of the first color under driving of the driving circuit substrate, where the forming the color conversion layer above the plurality of light-emitting units includes: forming a grid frame on the light-emitting unit; forming a grid hole at a position corresponding to the light-emitting unit in the grid frame, the grid hole at least exposing a light-emitting surface of the light-emitting unit; forming a second reflective layer at least on a side surface of the grid frame; and forming the first wavelength conversion units and second wavelength conversion units respectively in grid holes corresponding to the first light-emitting units and the second light-emitting units.

In an embodiment of the present disclosure, the forming the plurality of light-emitting units on the side of the driving circuit substrate further includes: forming third light-emitting units on the side of the driving circuit substrate, where light emitted by the third light-emitting units and light emitted by the first light-emitting units are of the same color; where the forming the color conversion layer above the plurality of light-emitting units further includes: forming light-transmitting structures in grid holes corresponding to the third light-emitting units, where the light-transmitting structures are configured to transmit the light of the first color emitted by the third light-emitting units.

In an embodiment of the present disclosure, the preparing method further includes: forming a second transmissive-reflective layer on the color conversion layer, where the second transmissive-reflective layer is configured to transmit light of other color and reflect the light of the first color.

In an embodiment of the present disclosure, the preparing method further includes: forming microlenses above the plurality of light-emitting units.

In an embodiment of the present disclosure, after forming the first reflective layer on the sidewall of the supporting unit and before forming the color conversion layer above the plurality of light-emitting units, the preparing method further includes: forming a plurality of supporting structures above the plurality of light-emitting units using a dam process, a gap existing between two adjacent supporting structures, and the gap corresponding to the light-emitting unit; and forming a third reflective layer on a sidewall of each of the plurality of supporting structures.

According to the micro-display chip structure provided by the present disclosure, a supporting frame is disposed on the driving circuit substrate. The supporting frame includes the plurality of supporting units, each supporting unit is disposed corresponding to the light-emitting unit and covers the sidewall of the light-emitting unit. The sidewall of the supporting unit is covered with the first reflective layer. In this way, crosstalk between two adjacent light-emitting units may be prevented, that is, the first reflective layer serves an anti-crosstalk function. In addition, a structural combination where the supporting unit at least covers the sidewall of the light-emitting unit and the first reflective layer covers the sidewall of the supporting unit is adopted, there is no gap between the supporting unit and the light-emitting unit, and therefore, when preparing the supporting unit and the first reflective layer, it is only necessary to directly deposit the supporting unit without requiring photolithography and etching. This simplifies a method for preparing the supporting unit and prevents damage to the light-emitting unit during a process of preparing the supporting unit. Furthermore, since there is no gap between the supporting unit and the light-emitting unit, a reflective layer may be deposited over an entire surface above the supporting unit, and then the reflective layer is subjected to an overall etching to form the first reflective layer. That is, during the overall etching process of the reflective layer, process difficulty of the overall etching is reduced.

### BRIEF DESCRIPTION OF THE DRAWINGS

The above and other purposes, features, and advantages of the present disclosure become more apparent through a more detailed description of the embodiments of the present disclosure in conjunction with drawings. The drawings are intended to provide a further understanding of the embodiments of the present disclosure and constitute a portion of the specification, and the drawings are used for explaining the present disclosure with the embodiments of the present disclosure and do not constitute limitations on the present disclosure. In the drawings, same reference numerals generally represent same components or steps.

FIG. 1 is a schematic structural diagram of a micro-display chip structure according to an embodiment of the present disclosure.

FIG. 2 is a schematic structural diagram of a micro-display chip structure according to another embodiment of the present disclosure.

FIG. 3 is a schematic structural diagram of a micro-display chip structure according to another embodiment of the present disclosure.

FIG. 4 is a schematic structural diagram of a micro-display chip structure according to another embodiment of the present disclosure.

FIG. 5 is a schematic spectral diagram of reflection of red excitation light and green excitation light, and transmission of blue excitation light by a first transmissive-reflective layer in an embodiment of the present disclosure.

FIG. 6 is a schematic structural diagram of a micro-display chip structure according to another embodiment of the present disclosure.

FIG. 7 is a schematic structural diagram of a micro-display chip structure according to another embodiment of the present disclosure.

FIG. 8 is a schematic structural diagram of a micro-display chip structure according to another embodiment of the present disclosure.

FIG. 9 is a schematic structural diagram of a micro-display chip structure according to another embodiment of the present disclosure.

FIG. 10 is a schematic flowchart of a preparing method for a micro-display chip structure according to an embodiment of the present disclosure.

FIG. 11 is a schematic cross-sectional structural diagram of a driving circuit substrate and a light-emitting unit in a micro-display chip structure according to an embodiment of the present disclosure.

FIG. 12 is a schematic cross-sectional structural diagram of a driving circuit substrate, a light-emitting unit, and an etching stop layer in a micro-display chip structure according to an embodiment of the present disclosure.

FIG. 13 is a schematic cross-sectional structural diagram of a driving circuit substrate, a light-emitting unit, an etching stop layer, and a supporting frame in a micro-display chip structure according to an embodiment of the present disclosure.

FIG. 14 is a schematic cross-sectional structural diagram of a driving circuit substrate, a light-emitting unit, an etching stop layer, a supporting frame, and a first reflective layer in a micro-display chip structure according to an embodiment of the present disclosure.

FIG. 15 is a schematic cross-sectional structural diagram of a driving circuit substrate, a light-emitting unit, an etching stop layer, a supporting frame, a first reflective layer, and a color conversion layer in a micro-display chip structure according to an embodiment of the present disclosure.

FIG. 16 is a schematic cross-sectional structural diagram of a driving circuit substrate, a light-emitting unit, an etching stop layer, a supporting frame, and a reflective layer in a micro-display chip structure according to an embodiment of the present disclosure.

FIG. 17 is a schematic cross-sectional structural diagram of a driving circuit substrate, a light-emitting unit, an etching stop layer, a supporting frame, a first reflective layer, and a planarization layer in a micro-display chip structure according to an embodiment of the present disclosure.

FIG. 18 is a schematic cross-sectional structural diagram of a driving circuit substrate, a light-emitting unit, an etching stop layer, a supporting frame, a first reflective layer, a planarization layer, and a first transmissive-reflective layer in a micro-display chip structure according to an embodiment of the present disclosure.

FIG. 19 is a schematic cross-sectional structural diagram of a driving circuit substrate, a light-emitting unit, an etching stop layer, a supporting frame, a first reflective layer, a planarization layer, and a first transmissive-reflective layer in a micro-display chip structure according to another embodiment of the present disclosure.

FIG. 20 is a schematic cross-sectional structural diagram of a driving circuit substrate, a light-emitting unit, an etching stop layer, a supporting frame, a first reflective layer, a planarization layer, and a first transmissive-reflective layer in a micro-display chip structure according to another embodiment of the present disclosure.

FIG. 21 is a schematic cross-sectional structural diagram of a driving circuit substrate, a light-emitting unit, an etching stop layer, a supporting frame, a first reflective layer, a planarization layer, and a thermal insulation layer in a micro-display chip structure according to an embodiment of the present disclosure.

FIG. 22 is a schematic cross-sectional structural diagram of a grid frame in a micro-display chip structure according to an embodiment of the present disclosure.

FIG. 23 is a schematic cross-sectional structural diagram of a second reflective layer and a grid frame in a micro-display chip structure according to an embodiment of the present disclosure.

FIG. 24 is a schematic cross-sectional structural diagram of a light-emitting unit in a micro-display chip structure according to an embodiment of the present disclosure.

FIG. 25 is a schematic cross-sectional structural diagram of a second reflective layer in a micro-display chip structure according to an embodiment of the present disclosure.

FIG. 26 is a schematic cross-sectional structural diagram of a microlens in a micro-display chip structure according to an embodiment of the present disclosure.

FIG. 27 is a schematic cross-sectional structural diagram of a supporting frame and a third reflective layer in a micro-display chip structure according to an embodiment of the present disclosure.

### DETAILED DESCRIPTION OF THE EMBODIMENTS

In the description of the present disclosure, “a plurality of” means at least two, such as two, three, or the like, unless otherwise explicitly and specifically defined. All directional indications (such as up, down, left, right, front, back, top, bottom, ...) in the embodiments of the present disclosure are only used for explaining relative positional relationships, movement conditions, and the like, between various components in a specific posture (as shown in the drawings). If the specific posture changes, the directional indications also change accordingly. In addition, terms “include” and “have” and any variations thereof are intended to cover non-exclusive inclusion. For example, a process, a method, a system, a product, or a device that includes a series of steps or units is not limited to listed steps or units, but may optionally also include steps or units not listed, or optionally also include other steps or units inherent to the process, method, system, product, or device.

Furthermore, reference to “an embodiment” herein means that a specific feature, structure, or characteristic described in connection with the embodiment may be included in at least an embodiment of the present disclosure. The appearance of this phrase in various places in the specification is not necessarily referring to a same embodiment, nor is it an independent or alternative embodiment that is mutually exclusive with other embodiments. Those skilled in the art explicitly and implicitly understand that the embodiments described herein may be combined with other embodiments.

The technical solutions in the embodiments of the present disclosure are clearly and completely described below in conjunction with the drawings in the embodiments of the present disclosure. Apparently, described embodiments are only a portion of the embodiments of the present disclosure, but not all of them. Based on the embodiments of the present disclosure, all other embodiments obtained by those of ordinary skill in the art without creative work shall fall within the protection scope of the present disclosure.

In the related art, a display chip structure includes a grid frame, which has a grid hole, and a light-emitting unit is disposed in the grid hole. Therefore, during a process of preparing the grid frame, it is usually necessary to firstly prepare the light-emitting unit, and then the grid frame is formed around the light-emitting unit through a photolithography and etching process. There is a gap between the grid frame and the light-emitting unit, and a reflective layer (prepared by depositing a reflective layer over the entire surface followed by an etching process) is covered on a sidewall of the grid frame and on the light-emitting unit to serve an anti-crosstalk function. However, the photolithography and etching process for preparing the grid frame is complex, and after photolithography and etching, there is a gap between the grid frame and the light-emitting unit. In other words, when the photolithography and etching process is adopted to prepare the grid frame, certain damage may be caused to the light-emitting unit.

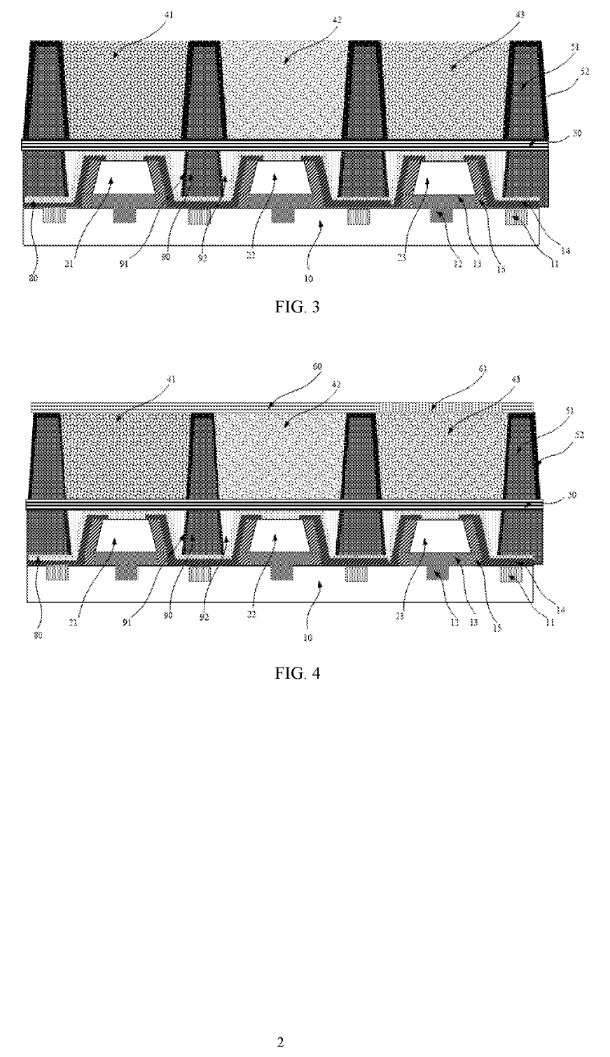

FIG. 1, FIG. 3 to FIG. 6 are schematic structural diagrams of a micro-display chip structure according to the embodiments of the present disclosure. As shown in FIG. 1, FIG. 3 to FIG. 6, the micro-display chip structure includes: a driving circuit substrate 10; a plurality of light-emitting units disposed on the driving circuit substrate 10 and spaced apart from each other; a color conversion layer disposed on a side of the plurality of light-emitting units away from the driving circuit substrate 10; a supporting frame disposed above the driving circuit substrate 10; and a first reflective layer 91.

Specifically, the driving circuit substrate 10 includes a substrate, a driving circuit located on a side of the substrate, and a plurality of contacts electrically connected to the driving circuit. A material of the substrate may include a semiconductor material such as silicon, silicon carbide, gallium nitride, germanium, gallium arsenide, or indium phosphide, or may also include a non-conductive material such as glass, plastic, or sapphire wafers. The driving circuit includes but is not limited to a complementary metal-oxide-semiconductor device (CMOS device), a thin-film transistor device (TFT device), or the like. The contacts include a first contact 12 and a second contact 11.

The plurality of light-emitting units may include: first light-emitting units 21, second light-emitting units 22, and third light-emitting units 23. The first light-emitting units 21, the second light-emitting units 22, and the third light-emitting units 23 emit light under independent driving of the driving circuit substrate 10. Specifically, the light-emitting unit includes: a first electrode layer 13, an LED epitaxial structure layer, and a second electrode layer 14 stacked on the driving circuit substrate 10 in sequence, where the first electrode layer 13 is electrically connected to the first contact 12, and the second electrode layer 14 is electrically connected to the second contact 11. Through the first contact 12 and the second contact 11, the driving circuit applies a first voltage to the first electrode layer 13 and a second voltage to the second electrode layer 14, causing the LED epitaxial structure layer to emit light under driving of the first voltage and the second voltage which have a voltage difference. Optionally, a passivation layer 15 is further provided between the first electrode layer 13 and the second electrode layer 14, and the passivation layer 15 is used for electrical insulation. Optionally, the first electrode layer 13 may be an anode layer, and the second electrode layer 14 may be a cathode layer. As shown in FIG. 1, FIG. 3 to FIG. 6, the plurality of light-emitting units share a cathode layer. Similarly, the plurality of light-emitting units may also share an anode layer. The first light-emitting units 21 emit light of a first color under the driving of the driving circuit substrate. Optionally, the light-emitting unit may be a micro inorganic light-emitting diode, for example: a blue light-emitting diode, or may be an ultraviolet light-emitting diode.

The color conversion layer at least includes first wavelength conversion units 41. The first wavelength conversion units are disposed corresponding to the first light-emitting units 21, and the first wavelength conversion units 41 may convert the light of the first color emitted by the first light-emitting units 21 into light of a second color.

The supporting frame includes a plurality of supporting units 92, each supporting unit of the supporting units 92 is disposed corresponding to each light-emitting unit and at least covers a sidewall of the light-emitting unit. Optionally, the supporting unit 92 is a transparent supporting unit 92, that is, the supporting unit 92 is prepared from a transparent material, for example, transparent negative photoresist, silicon oxide, silicon nitride, or the like.

The first reflective layer 91 at least covers a sidewall of the supporting unit 92. The first reflective layer 91 may serve an anti-crosstalk function. Specifically, a material of the first reflective layer 91 may be a material such as metal Al, Ag, or the like, which may reflect light.

According to the micro-display chip structure provided by the present disclosure, a supporting frame is disposed on the driving circuit substrate. The supporting frame includes the plurality of supporting units 92, each supporting unit of the supporting units 92 is disposed corresponding to each light-emitting unit, and the supporting unit 92 covers the sidewall of the light-emitting unit. The sidewall of the supporting unit 92 is covered with the first reflective layer 91. In this way, crosstalk between two adjacent light-emitting units may be prevented, that is, the first reflective layer 91 serves an anti-crosstalk function. In addition, a structural combination where the supporting unit 92 at least covers the sidewall of the light-emitting unit and the first reflective layer 91 covers the sidewall of the supporting units 92 is adopted, there is no gap between the supporting unit 92 and the light-emitting unit, and therefore, when preparing the supporting unit 92 and the first reflective layer 91, it is only necessary to directly deposit the supporting unit 92 without requiring photolithography and etching. This simplifies a method for preparing the supporting unit 92, and prevents damage to the light-emitting unit during a process of preparing the supporting unit 92. Furthermore, since there is no gap between the supporting unit 92 and the light-emitting unit, a reflective layer may be deposited over the entire surface on the supporting unit 92, and then the reflective layer may be subjected to an overall etching to form the first reflective layer 91. That is, during the overall etching process of the reflective layer, process difficulty of the overall etching is reduced. That is, the embodiments of the present disclosure may simplify the preparation process of the micro-display chip structure and reduce a risk of damage to the light-emitting unit caused by partial etching processes during the preparation process of the micro-display chip structure.

In an embodiment of the present disclosure, as shown in FIG. 1, the supporting unit 92 has an inclined sidewall, that is, a structure of the supporting unit 92 is a bowl-shaped structure. Since the first reflective layer 91 covers the sidewall of the supporting unit 92, that is, the first reflective layer 91 covers the sidewall of the bowl-shaped supporting unit 92, it may not only serve an anti-crosstalk function but also improve light focusing effect and enhance brightness.

In an embodiment of the present disclosure, as shown in FIG. 1, the micro-display chip structure further includes: a planarization layer 90, which fills a gap between two adjacent supporting units 92 to form a flat top surface.

In an embodiment of the present disclosure, as shown in FIG. 1, the plurality of light-emitting units further include second light-emitting units 22. Light emitted by the second light-emitting units 22 and light emitted by the first light-emitting units 21 are of the same color, that is, the second light-emitting unit 22 emits the light of the first color. The color conversion layer further includes second wavelength conversion units 42. The second wavelength conversion units 42 are disposed corresponding to the second light-emitting units 22. The second wavelength conversion unit 42 is configured to convert the light of the first color emitted by the second light-emitting unit 22 into light of a third color. Through an arrangement of the second light-emitting units 22 and the second wavelength conversion units 42, the light of the first color emitted by the first light-emitting units 21 and the second light-emitting units 22 is converted by the first wavelength conversion units 41 and the second wavelength conversion units 42 into the light of the second color and the light of the third color respectively, so as to achieve colorization of a micro-display (for example, a Micro-LED display).

Optionally, as shown in FIG. 1, the plurality of light-emitting units further include third light-emitting units 23. Light emitted by the third light-emitting units 23 and the light emitted by the first light-emitting units 21 are of the same color, that is, the third light-emitting unit 23 emits the light of the first color. The color conversion layer further includes light-transmitting structures 43. The light-transmitting structures 43 transmit the light of the first color emitted by the third light-emitting units 23. The light-transmitting structures 43 are disposed corresponding to the third light-emitting units 23. That is, the plurality of light-emitting units include the first light-emitting units 21, the second light-emitting units 22, and the third light-emitting units 23, and all emit the light of the first color. The color conversion layer includes the first wavelength conversion units 41, the second wavelength conversion units 42, and the light-transmitting structures 43. The first wavelength conversion units 41, the second wavelength conversion units 42, and the light-transmitting structures 43 are disposed corresponding to the first light-emitting units 21, the second light-emitting units 22, and the third light-emitting units 23, respectively. The first wavelength conversion units 41 and the second wavelength conversion units 42 convert the light of the first color emitted by the first light-emitting units 21 and the second light-emitting units 22 into the light of the second color and the light of the third color, respectively. The light-transmitting structures 43 transmit the light of the first color emitted by the third light-emitting units 23. Specifically, a quantum dot material in the first wavelength conversion units 41 and the second wavelength conversion units 42 includes one or two or more of CdSe, CdS, CdZnSe, CdZnS, CdZnSeS, ZnSeS, ZnSe, CuInS, CuInSe, InP, InZnP.

The light of the first color emitted by the first light-emitting units 21 and the second light-emitting units 22 is converted by the first wavelength conversion units 41 and the second wavelength conversion units 42 into the light of the second color and the light of the third color respectively. Through an arrangement of the third light-emitting units 23 and the light-transmitting structures 43, the light of the first color emitted by the third light-emitting unit 23 remains the light of the first color after passing through the light-transmitting structure 43, so that the micro-display (for example, a Micro-LED display) emits three colors of light, achieving full colorization. That is, at least one first light-emitting unit 21, at least one second light-emitting unit 22, and at least one third light-emitting unit 23 are combined to form a full-color pixel point.

Specifically, the light of the first color, the light of the second color, and the light of the third color may be blue light, red light, and green light, respectively. Correspondingly, the light-transmitting structure 43 transmits blue light. The first wavelength conversion unit 41 and the second wavelength conversion unit 42 are filled with wavelength conversion materials, for example, they may be filled with red fluorescent material and green fluorescent material, respectively, or may be filled with quantum dot materials, or the like.

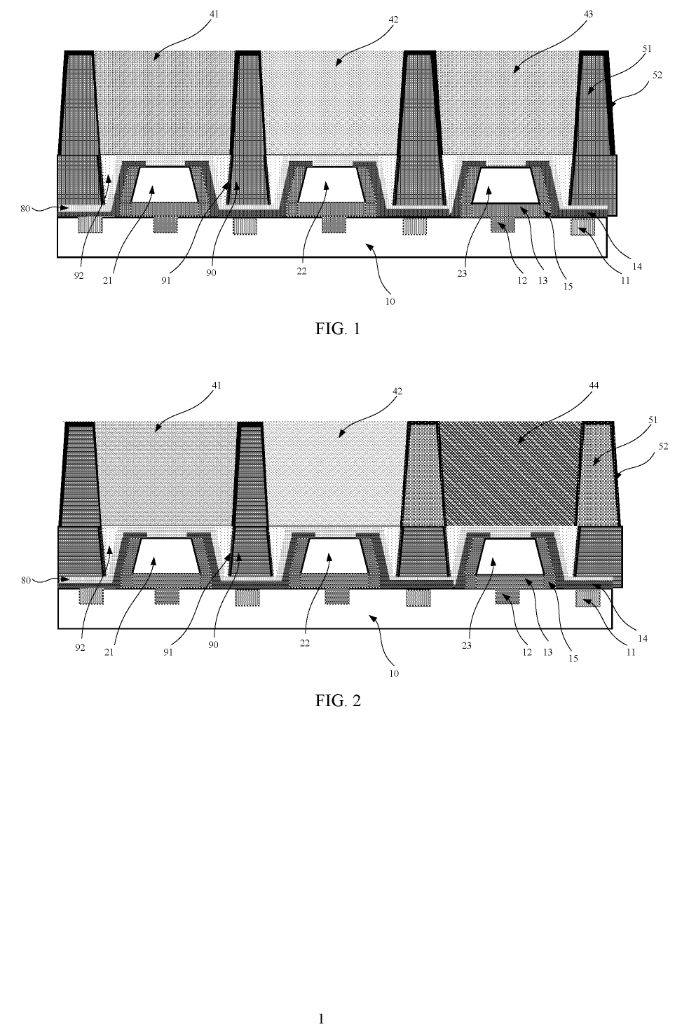

Optionally, as shown in FIG. 2, the plurality of light-emitting units further includes third light-emitting units 23. Light emitted by the third light-emitting units and the light emitted by the first light-emitting units 21 are of the same color, that is, the third light-emitting unit 23 emits the light of the first color. The color conversion layer further includes third wavelength conversion units 44. The third wavelength conversion units 44 are disposed corresponding to the third light-emitting units 23. The third wavelength conversion unit 44 converts the light of the first color emitted by the third light-emitting unit 23 into light of a fourth color. Specifically, the first light-emitting unit 21, the second light-emitting unit 22, and the third light-emitting unit 23 are all ultraviolet light-emitting diodes, that is, the first light-emitting unit 21, the second light-emitting unit 22, and the third light-emitting unit 23 all emit ultraviolet light (the light of the first color), and after conversion by the first wavelength conversion unit 41, the second wavelength conversion unit 42, and the third wavelength conversion unit 44, the ultraviolet light is converted into blue light (the light of the second color), red light (the light of the third color), and green light (light of a fourth color), respectively.

In an embodiment of the present disclosure, as shown in FIG. 3 and FIG. 4, the micro-display chip structure further includes: a first transmissive-reflective layer 30 disposed between the light-emitting units and the color conversion layer. The first transmissive-reflective layer 30 transmits the light of the first color and reflects light of other color. Specifically, the first transmissive-reflective layer 30 is composed of a plurality of materials with different refractive indices alternately stacked in irregular thicknesses as fitted by simulation software. The first transmissive-reflective layer 30 may achieve higher reflection for a corresponding wavelength while achieving higher transmission for other wavelengths. For example, the first transmissive-reflective layer 30 may reflect the light of the second color and the light of the third color, and transmit the light of the first color.

The first transmissive-reflective layer 30 may transmit the light of the first color and reflect the light of the second color. The light of the first color emitted by the first light-emitting unit 21 passes through the first transmissive-reflective layer 30 and is converted into the light of the second color by the first wavelength conversion unit 41. At the same time, the first transmissive-reflective layer 30 reflects the light of the second color. That is, due to presence of the first transmissive-reflective layer 30, before the light of the first color is converted, selective filtering is firstly performed through the first transmissive-reflective layer 30, achieving higher reflectivity for the light of the second color and higher transmittance for the light of the first color, thereby improving absorbance and color purity of a fluorescent material or a quantum dot material in the first wavelength conversion unit 41, ensuring light emission purity of a sub-pixel region, and improving overall display screen color gamut.

Optionally, the light-emitting units further include the second light-emitting units 22 and the third light-emitting units 23. The first light-emitting units 21, the second light-emitting units 22, and the third light-emitting units 23 all emit the light of the first color. The color conversion layer further includes the first wavelength conversion units 41, the second wavelength conversion units 42, and the light-transmitting structures 43. The first wavelength conversion units 41, the second wavelength conversion units 42, and the light-transmitting structures 43 are disposed corresponding to the first light-emitting units 21, the second light-emitting units 22, and the third light-emitting units 23, respectively. The light-transmitting structure 43 transmits the light of the first color emitted by the third light-emitting unit 23. The first wavelength conversion unit 41 and the second wavelength conversion unit 42 convert the light of the first color emitted by the first light-emitting unit 21 and the second light-emitting unit 22 into the light of the second color and the light of the third color, respectively.

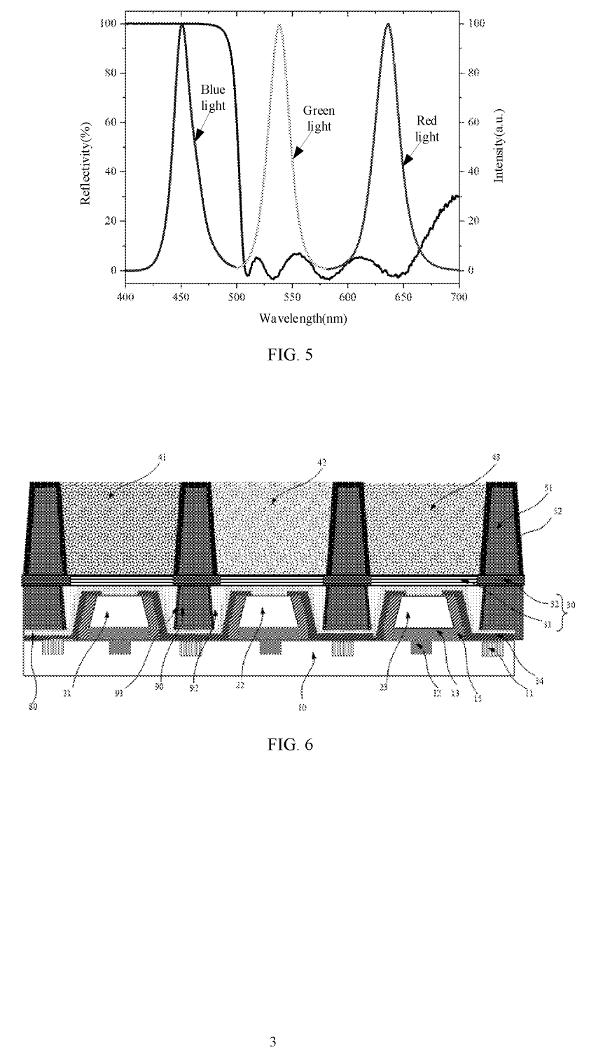

For example, FIG. 5 shows a schematic spectral diagram of the first transmissive-reflective layer 30 reflecting red light and green light and transmitting blue light, where a light-emitting unit is a blue light-emitting diode. The first transmissive-reflective layer 30 reflects red light and green light that may be mixed in the blue light emitted by the light-emitting units (for example, the first light-emitting units 21, the second light-emitting units 22, and the third light-emitting units 23) and transmits the blue light. Materials of the first wavelength conversion unit 41 and the second wavelength conversion unit 42 are a red fluorescent material and a green fluorescent material, respectively, so that the first wavelength conversion unit 41 may convert blue light into red light, and the second wavelength conversion unit 42 may convert blue light into green light. At the same time, the blue light emitted by the third light-emitting unit 23, after being transmitted by the first transmissive-reflective layer 30 and then transmitted again by the light-transmitting structure 43, remains blue light, so as to achieve three primary colors, thereby achieving full colorization of the micro-display (for example, a Micro-LED display).

Optionally, as shown in FIG. 6, the first transmissive-reflective layer 30 includes: a plurality of transmissive-reflective units 31, where the plurality of transmissive-reflective units 31 are disposed corresponding to the plurality of light-emitting units, respectively, and the transmissive-reflective unit 31 reflects the light of the second color and the light of the third color, and transmits the light of the first color; and a light-blocking structure 32 disposed between two adjacent transmissive-reflective units 31; where the transmissive-reflective unit 31 covers a light-emitting surface of a corresponding light-emitting unit. That is, the first transmissive-reflective layer 30 is divided into the plurality of transmissive-reflective units 31 by the light-blocking structure 32, and the transmissive-reflective unit 31 is a divided portion of the first transmissive-reflective layer 30. A specific implementation method may be: a plurality of through holes are provided in a continuous first transmissive-reflective layer 30, and the light-blocking structure 32 is filled in the through holes, and thus the light-blocking structure 32 may divide the first transmissive-reflective layer 30 into the plurality of transmissive-reflective units 31. The transmissive-reflective unit 31 is disposed corresponding to the light-emitting unit, and the transmissive-reflective unit 31 covers the light-emitting surface of the corresponding light-emitting unit. By arranging the light-blocking structure 32 on the first transmissive-reflective layer 30, a phenomenon of mutual crosstalk between excitation light emitted by adjacent light-emitting units is prevented, thus serving an anti-crosstalk function.

Optionally, the light-blocking structure 32 may be a black photoresist structure or a metal reflective layer.

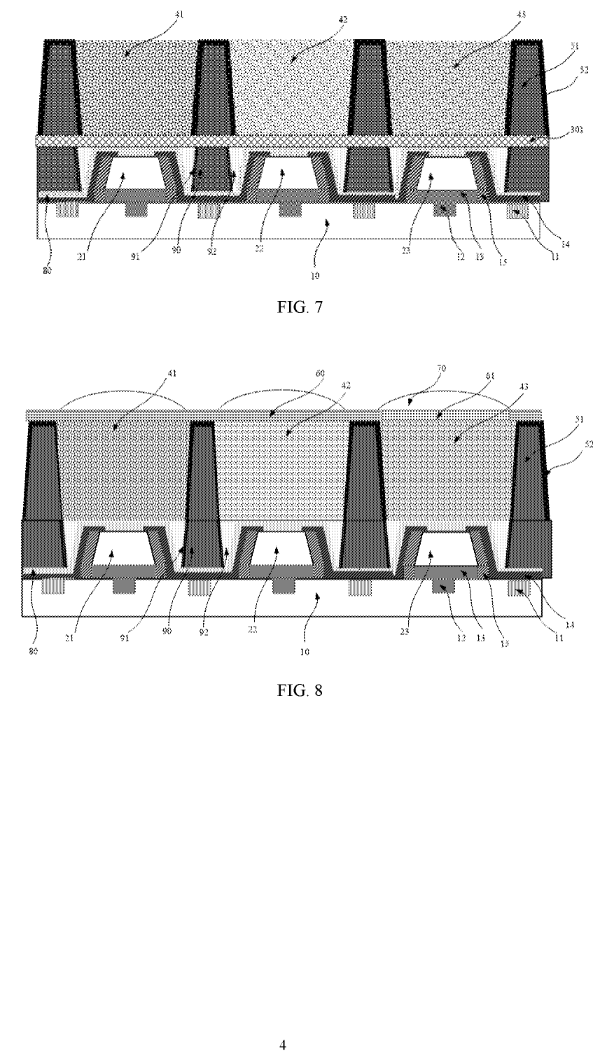

In an embodiment of the present disclosure, as shown in FIG. 7, the micro-display chip structure further includes: a thermal insulation layer 301 disposed between the light-emitting unit and the color conversion layer. The thermal insulation layer 301 at least transmits the light of the first color. The thermal insulation layer 301 may reduce an impact of heat generated by the light-emitting unit on the color conversion layer, thereby improving service life of the color conversion layer.

In an embodiment, both the first transmissive-reflective layer 30 and the thermal insulation layer 301 may be disposed between the light-emitting unit and the color conversion layer. The thermal insulation layer 301 may be disposed on a side of the first transmissive-reflective layer 30 away from the light-emitting unit or away from the color conversion layer.

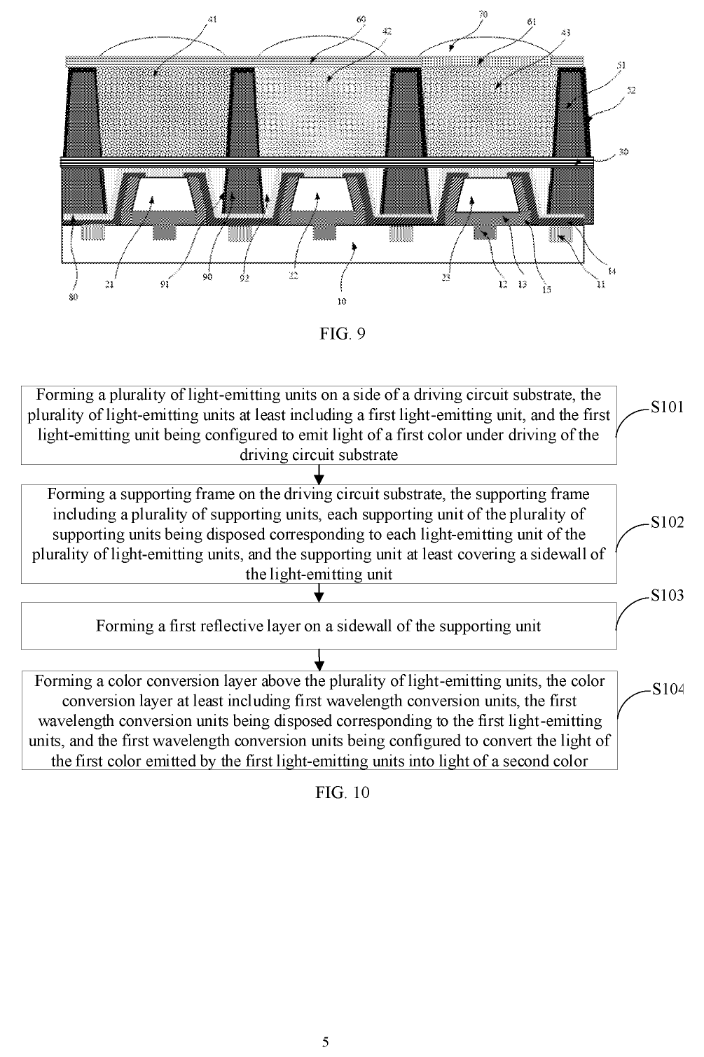

In an embodiment of the present disclosure, as shown in FIG. 8 and FIG. 9, the micro-display chip structure further includes: a second transmissive-reflective layer 60 disposed above the color conversion layer. The second transmissive-reflective layer 60 transmits light of other color (such as the light of the second color) and reflects the light of the first color.

Specifically, the second transmissive-reflective layer 60 includes at least five groups of film layers. Materials of two film layers in each group of film layers are any two materials selected from: TiO₂, SiO₂, SiNx, HfO₂, MgF₂, ZrO₂, and PMMA.

After the light of the second color emitted by the first wavelength conversion unit 41 passes through the second transmissive-reflective layer 60, the second transmissive-reflective layer 60 may further filter out the light of the first color that may be mixed in the light of the second color, improving the light emission purity of the sub-pixel region and improving color gamut of the overall display screen. At the same time, the second transmissive-reflective layer 60 reflects the light of the first color mixed in the light of the second color back into the first wavelength conversion unit 41, so that the light of the first color not converted by the first wavelength conversion unit 41 is absorbed and converted again by the first wavelength conversion unit 41, thereby improving absorption and conversion capabilities of the wavelength conversion material in a wavelength conversion unit.

Optionally, as shown in FIG. 8 and FIG. 9, the light-emitting units further include the aforementioned second light-emitting units 22 and third light-emitting units 23. The color conversion layer further includes the second wavelength conversion units 42 and the light-transmitting structures 43. That is, the second wavelength conversion unit 42 is disposed corresponding to the second light-emitting unit 22, and the light-transmitting structure 43 is disposed corresponding to the third light-emitting unit 23. The second transmissive-reflective layer 60 transmits the light of the third color. Further, the second transmissive-reflective layer 60 has an opening, a transmissive unit 61 is disposed in the opening, and the transmissive unit 61 is used for transmitting the light of the first color.

After the light of the third color emitted by the second wavelength conversion unit 42 passes through the second transmissive-reflective layer 60, the second transmissive-reflective layer 60 may transmit the light of the third color and further filter out the light of the first color that may be mixed in the light of the third color, improving the light emission purity of the sub-pixel region and improving the color gamut of the overall display screen. At the same time, the second transmissive-reflective layer 60 reflects the light of the first color mixed in the light of the third color back into the second wavelength conversion unit 42, so that the light of the first color not converted by the second wavelength conversion unit 42 is absorbed and converted again by the second wavelength conversion unit 42, improving the absorption and conversion capabilities of the wavelength conversion material in the wavelength conversion unit. At the same time, the light of the first color emitted by the third light-emitting unit 23 is transmitted by the light-transmitting structure 43 and then transmitted by the transmissive unit 61.

Specifically, a material of the transmissive unit 61 may be a light-transmitting material, which serves to transmit the light of the first color, and may also serve a planarization function. Alternatively, the material of the transmissive unit 61 may be a filtering material, only allowing transmission of the light of the first color and reflecting the light of the second color and the light of the third color.

Optionally, as shown in FIG. 9, the micro-display chip structure includes not only the aforementioned first transmissive-reflective layer 30 (disposed between the light-emitting unit and the color conversion layer) but also the aforementioned second transmissive-reflective layer 60 (disposed above the color conversion layer). The first transmissive-reflective layer 30 reflects the light of the second color and the light of the third color, and transmits the light of the first color, while the second transmissive-reflective layer 60 transmits the light of the second color and the light of the third color, and reflects the light of the first color. The plurality of light-emitting units include: the first light-emitting units 21, the second light-emitting units 22, and the third light-emitting units 23. The first light-emitting units 21, the second light-emitting units 22, and the third light-emitting units 23 emit blue light under individual driving of the driving circuit substrate. The color conversion layer includes: the first wavelength conversion units 41, the second wavelength conversion units 42, and the light-transmitting structures 43. The first wavelength conversion units 41, the second wavelength conversion units 42, and the light-transmitting structures 43 are respectively disposed corresponding to the first light-emitting units 21, the second light-emitting units 22, and the third light-emitting units 23. The first wavelength conversion unit 41 and the second wavelength conversion unit 42 respectively convert blue light into red light and green light, and blue light passes through the light-transmitting structure 43. After the blue light emitted by the light-emitting unit passes through the first transmissive-reflective layer 30, the first transmissive-reflective layer 30 firstly performs selective filtering on the blue light, achieving higher reflectivity for red light and green light and higher transmittance for blue light. After passing through the first transmissive-reflective layer 30, the blue light passes through the first wavelength conversion unit 41 and the second wavelength conversion unit 42 and is converted into red light and green light, respectively. After passing through the first transmissive-reflective layer 30, the blue light transmitted through the light-transmitting structure 43 remains blue light. After the red light, green light, and blue light pass through the second transmissive-reflective layer 60, the second transmissive-reflective layer 60 may further filter out any blue light that may be mixed in the red light and the green light, improving the light emission purity of the sub-pixel region and enhancing color gamut of an overall display screen. At the same time, the second transmissive-reflective layer 60 reflects the blue light that may be mixed in the red light and green light back into a corresponding first wavelength conversion unit 41 and a corresponding second wavelength conversion unit 42, so that unconverted blue light is absorbed and converted again, thereby improving the absorption and conversion capabilities of the wavelength conversion material in the wavelength conversion unit.

In an embodiment of the present disclosure, as shown in FIG. 8 and FIG. 9, the micro-display chip structure further includes: a plurality of microlenses 70 disposed above the color conversion layer, where the plurality of microlenses 70 are disposed corresponding to the plurality of light-emitting units. The microlens 70 is an important optical component characterized by small size, light weight, and high integration. The microlens 70 is used for converging or diverging light radiation. By disposing the microlens 70 in the embodiments of the present disclosure, a light emission angle may be reduced, thereby achieving convergence of converted light and enhancing a light emission effect.

In an embodiment, the second transmissive-reflective layer 60 and the plurality of microlenses 70 may be simultaneously disposed above the color conversion layer. The plurality of microlenses 70 may be disposed on a side of the second transmissive-reflective layer 60 away from or close to the color conversion layer.

In an embodiment of the present disclosure, as shown in FIG. 1 to FIG. 3 and FIG. 5 to FIG. 9, the micro-display chip structure further includes: a grid frame 51 disposed above the light-emitting units. The grid frame 51 has a plurality of grid holes, and the plurality of grid holes are disposed corresponding to the plurality of light-emitting units. A bottom of each grid hole exposes the corresponding light-emitting unit, and the first wavelength conversion unit 41 is disposed in the grid hole.

Optionally, when the light-emitting units further include the aforementioned second light-emitting units 22 and the third light-emitting units 23, and the color conversion layer further includes the second wavelength conversion units 42 and the light-transmitting structures 43, the second wavelength conversion units 42 are disposed corresponding to the second light-emitting units 22, and the light-transmitting structures 43 are disposed corresponding to the third light-emitting units 23. Both the second wavelength conversion units 42 and the light-transmitting structures 43 are correspondingly disposed in the grid holes.

Optionally, the grid hole is a tapered hole structure with an inclined sidewall, which may improve light concentration and enhance brightness.

Specifically, a material of the grid frame 51 may be organic resin, organic black matrix photoresist, color filter photoresist, polyimide, or the like.

Optionally, as shown in FIG. 1 to FIG. 3 and FIG. 5 to FIG. 9, the micro-display chip structure further includes a second reflective layer 52, which at least covers the sidewall of the grid hole.

Specifically, a material of the second reflective layer 52 may be a reflective material such as metal Al or Ag.

In this embodiment, the grid frame 51 and the second reflective layer 52 form a light-blocking structure between two adjacent light-emitting units, serving an anti-crosstalk function. Additionally, a bowl-shaped structure of the grid frame 51 and the second reflective layer 52 may improve light concentration and enhance brightness.

In an embodiment of the present disclosure, as shown in FIG. 1 to FIG. 3 and FIG. 5 to FIG. 9, the micro-display chip structure further includes an etching stop layer 80, which covers the driving circuit substrate 10, as well as the light-emitting surface and side surfaces of the light-emitting units. The etching stop layer 80 may prevent damage to the light-emitting unit during an etching process, thereby protecting the light-emitting unit. Optionally, the etching stop layer 80 may be made of a light-transmitting material such as SiO₂.

Exemplary preparing method

As a second aspect of the present disclosure, the present disclosure further provides a preparing method for a micro-display chip structure, configured to prepare the aforementioned micro-display chip structure. FIG. 10 shows a schematic flowchart of a preparing method for a micro-display chip structure according to an embodiment of the present disclosure. As shown in FIG. 10, the preparing method for the micro-display chip structure includes following steps:

S101: forming a plurality of light-emitting units on a side of a driving circuit substrate 10, the plurality of light-emitting units at least including a first light-emitting units 21, and the first light-emitting units 21 being configured to emit light of a first color under driving of the driving circuit substrate 10.

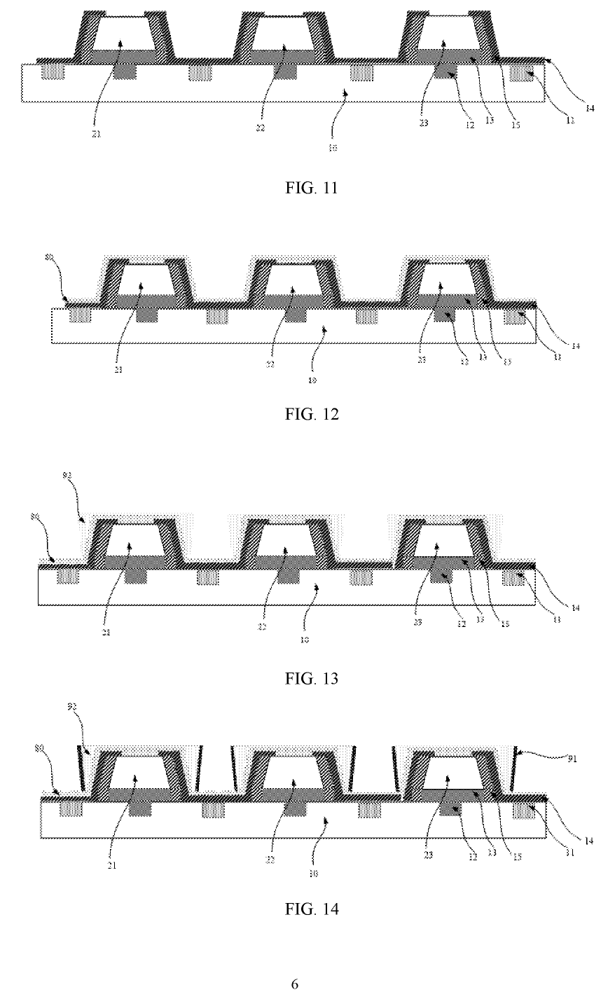

Specifically, as shown in FIG. 11, the driving circuit substrate 10 includes a substrate, a driving circuit located on a side of the substrate, and a plurality of contacts electrically connected to the driving circuit. A material of the substrate may include a semiconductor material such as silicon, silicon carbide, gallium nitride, germanium, gallium arsenide, or indium phosphide, or may also include a non-conductive material such as glass, plastic, or sapphire wafers. The driving circuit includes but is not limited to a complementary metal-oxide-semiconductor device (CMOS device), a thin-film transistor device (TFT device), or the like. The contacts include a first contact 12 and a second contact 11. In an example, the number of the first light-emitting units 21 may be one or more.

As shown in FIG. 11, the forming the plurality of light-emitting units on the side of the driving circuit substrate 10 includes:

sequentially stacking a first electrode layer 13, an LED epitaxial structure layer, and a second electrode layer 14 on the driving circuit substrate 10, where the first electrode layer 13 is electrically connected to the first contact 12, and the second electrode layer 14 is electrically connected to the second contact 11. Through the first contact 12 and the second contact 11, the driving circuit substrate applies a first voltage to the first electrode layer 13 and a second voltage to the second electrode layer 14, causing the LED epitaxial structure layer to emit light under driving of the first voltage and the second voltage which have a voltage difference. Optionally, a passivation layer 15 is further formed between the first electrode layer 13 and the second electrode layer 14, and the passivation layer 15 is used for electrical insulation.

S102: forming a supporting frame on the driving circuit substrate 10, the supporting frame including a plurality of supporting units 92, each supporting unit 92 of the plurality of supporting units 92 being disposed corresponding to each light-emitting unit of the plurality of light-emitting units, and the supporting unit 92 at least covering a sidewall of the light-emitting unit, as shown in FIG. 13.

Optionally, the supporting unit 92 is a transparent supporting unit, that is, the supporting unit 92 is prepared from a transparent material, such as transparent negative photoresist, silicon oxide, silicon nitride, or the like. For example, the transparent negative photoresist is adopted to form the supporting unit 92 around the light-emitting unit.

After forming the supporting unit 92 around the light-emitting unit, there is no gap between the supporting unit 92 and the light-emitting unit covered by the supporting unit 92.

In S102, the supporting unit 92 is directly deposited. Compared to the related art, the present disclosure does not require photolithography and etching, thereby simplifying a method for preparing the supporting unit 92 and avoiding damage to the light-emitting unit during a preparing process of the supporting unit 92.

Optionally, in an embodiment, before step S102, the preparing method may further include: forming an etching stop layer 80 on the driving circuit substrate 10. The etching stop layer 80 covers the driving circuit substrate 10, as well as the light-emitting surface and a side surface of the light-emitting unit. As shown in FIG. 12, the etching stop layer 80 may prevent damage to the light-emitting unit during an etching process, thereby protecting the light-emitting unit. Optionally, the etching stop layer 80 may be made of a light-transmitting material such as SiO₂.

S103: forming a first reflective layer 91 on a sidewall of the supporting unit 92, as shown in FIG. 14.

The first reflective layer 91 may prevent crosstalk between two adjacent light-emitting units, that is, it serves an anti-crosstalk function.

Optionally, a material of the first reflective layer 91 may be a reflective material such as metal Al or Ag.

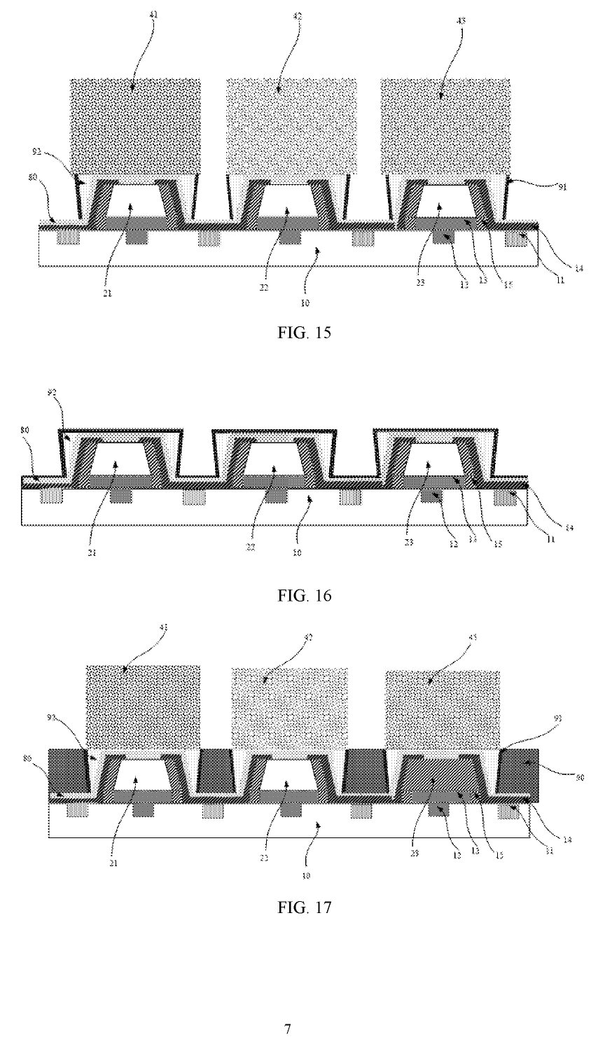

S104: forming a color conversion layer above the plurality of light-emitting units, the color conversion layer at least including first wavelength conversion units 41, the first wavelength conversion units 41 being disposed corresponding to the first light-emitting units 21, and the first wavelength conversion units being configured to convert the light of the first color emitted by the first light-emitting units 21 into light of a second color, as shown in FIG. 15.

According to the preparing method for the micro-display chip structure provided in the present disclosure, the supporting unit 92 is formed around the light-emitting unit, then the first reflective layer 91 is formed on the sidewall of the supporting unit 92, so that the first reflective layer 91 at least covers the sidewall of the supporting unit 92, thereby preventing crosstalk between two adjacent light-emitting units, that is, serving the anti-crosstalk function. The supporting unit 92 is prepared without requiring photolithography and etching, which simplifies the method for preparing the supporting unit 92 and avoids damage to the light-emitting unit during the preparing process of the supporting unit 92. Additionally, since there is no gap between the supporting unit 92 and the light-emitting unit, during formation of the first reflective layer 91, whether an etching process is required or not, the light-emitting unit is not contacted during the etching process, thereby further avoiding damage to the light-emitting unit caused by the photolithography and etching process.

In an embodiment of the present disclosure, S103 (forming the first reflective layer 91 on the sidewall of the supporting unit 92) specifically includes following steps:
(1) forming a reflective layer on the light-emitting unit, where the reflective layer covers the sidewall and an upper surface of the supporting unit 92, the light-emitting surface of the light-emitting unit, and a gap between two adjacent light-emitting units of the plurality of light-emitting units, that is, the reflective layer completely covers each region, as shown in FIG. 16; and
(2) removing, by an etching process, the reflective layer on the upper surface of the supporting unit 92, the reflective layer on the light-emitting surface of the light-emitting unit, and the reflective layer in the gap between the two adjacent light-emitting units, and at least retaining the reflective layer located on the sidewall of the supporting unit 92, as shown in FIG. 14, where the first reflective layer 91 is a reflective layer at least located on the sidewall of the supporting unit 92.

In the present disclosure, the reflective layer is deposited over the entire surface above the supporting unit 92, and then the reflective layer is subjected to an overall etching to form the first reflective layer 91. That is, during the overall etching process of the reflective layer, process difficulty of the overall etching is reduced.

In an embodiment of the present disclosure, between forming the first reflective layer 91 on the sidewall of the supporting unit 92 and forming the color conversion layer above the plurality of light-emitting units, the preparing method further includes following step:
forming a planarization layer 90 on the driving circuit substrate, where the planarization layer 90 fills a gap between two adjacent supporting units 92 of the plurality of supporting units to form a flat top surface, as shown in FIG. 17.

Specifically, a material of the planarization layer 90 may be any substance, such as organic black matrix, silicon oxide, organic resin, or the like.

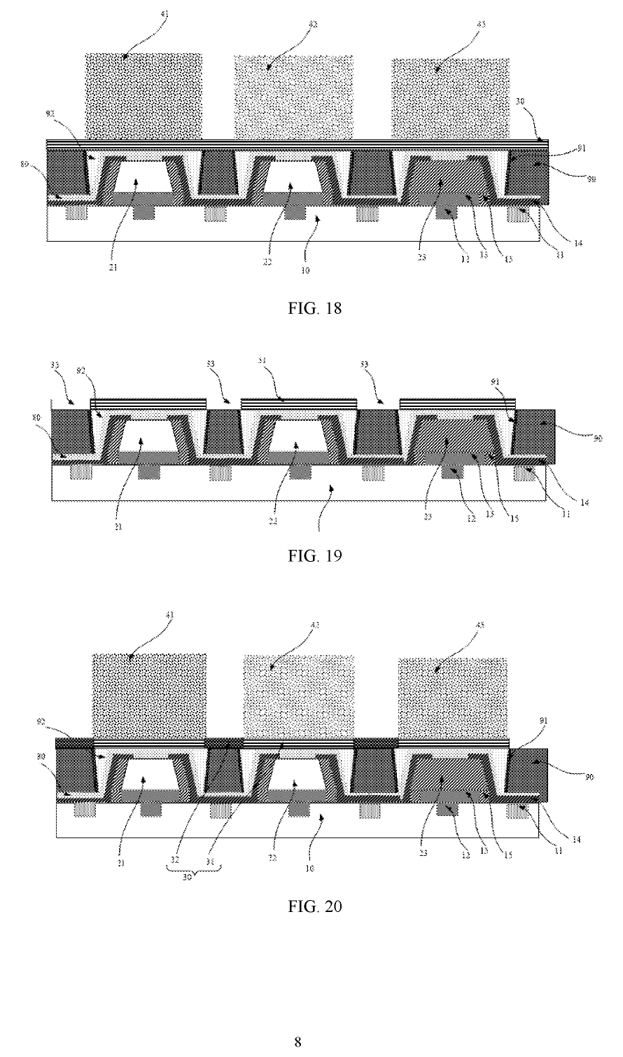

Optionally, between forming the planarization layer 90 on the driving circuit substrate and forming the color conversion layer above the plurality of light-emitting units, the preparing method further includes following step:
forming a first transmissive-reflective layer 30 on the planarization layer 90, where the first transmissive-reflective layer 30 is configured to transmit the light of the first color and reflect light of other color (such as the light of the second color), as shown in FIG. 18.

Before the light of the first color is converted, selective filtering is firstly performed through the first transmissive-reflective layer 30, achieving higher reflectivity for the light of the second color and higher transmittance for the light of the first color, thereby enhancing absorbance and color purity of a fluorescent material or quantum dot material in the first wavelength conversion unit 41, ensuring light emission purity of a sub-pixel region, and improving color gamut of an overall display screen.

Further, the forming the first transmissive-reflective layer 30 on the planarization layer 90 specifically includes following steps:

(1) forming a plurality of transmissive-reflective units 31 on the planarization layer 90 through an exposure and development process, where the plurality of transmissive-reflective units 31 are respectively disposed corresponding to the plurality of light-emitting units, and a through-hole 33 is provided between two adjacent transmissive-reflective units 31, as shown in FIG. 19.

The transmissive-reflective unit 31 covers the light-emitting surface of the corresponding light-emitting unit.

(2) forming a light-blocking structure 32, disposed between two adjacent transmissive-reflective units 31, as shown in FIG. 20. That is, the light-blocking structure 32 is formed in the through-hole 33 between two adjacent transmissive-reflective units 31.

Specifically, the light-blocking structure 32 may be a black photoresist structure or a metal reflective layer.

By disposing the light-blocking structure 32 on the first transmissive-reflective layer 30, a phenomenon of mutual crosstalk between excitation light emitted by adjacent light-emitting units is prevented, thus serving the anti-crosstalk function.

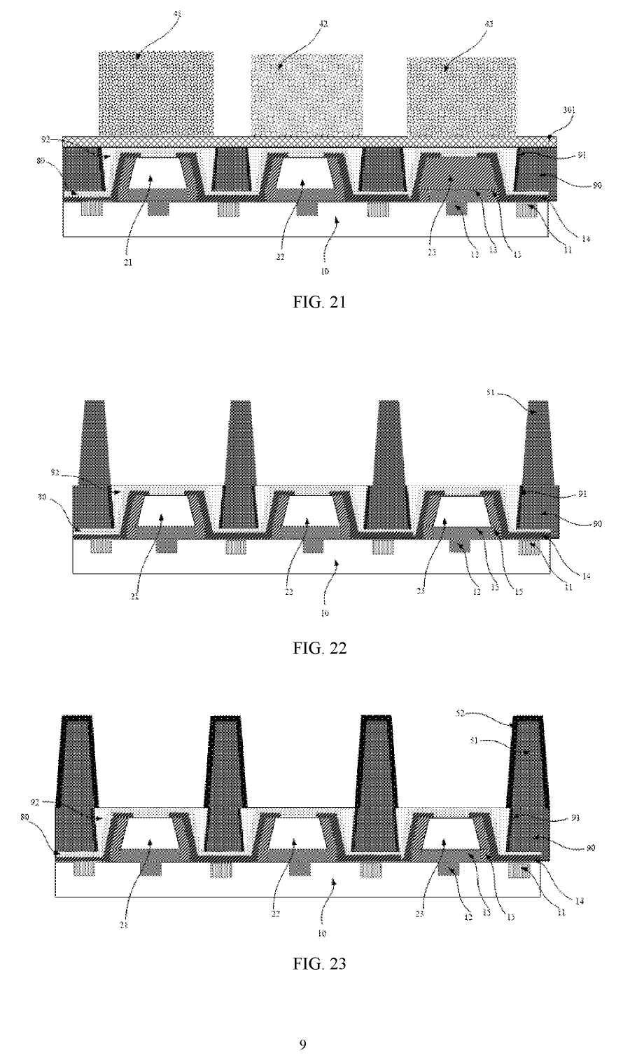

Alternatively, between forming the planarization layer 90 on the driving circuit substrate and forming the color conversion layer above the plurality of light-emitting units, the preparing method further includes following step:
forming a thermal insulation layer 301 on the planarization layer 90, as shown in FIG. 21.

The thermal insulation layer 301 is used for at least transmitting the light of the first color. The thermal insulation layer 301 may reduce an impact of heat generated by the light-emitting unit on the color conversion layer, thereby improving a service life of the color conversion layer.

Correspondingly, S104 actually involves forming the color conversion layer on the thermal insulation layer 301, as shown in FIG. 21.

In an embodiment of the present disclosure, S101 (forming the plurality of light-emitting units on the side of the driving circuit substrate) specifically includes following steps:
(1) forming the first light-emitting units 21 and the second light-emitting units 22 on the side of the driving circuit substrate, where the first light-emitting units 21 and the second light-emitting units 22 are used for emitting the light of the first color under the driving of the driving circuit substrate, as shown in FIG. 22.

S104 (forming the color conversion layer above the plurality of light-emitting units) specifically includes following steps:
(1) forming a grid frame 51 on the light-emitting unit, where a material of the grid frame 51 may be: organic resin, organic black matrix photoresist, color filter photoresist, polyimide, or the like.
(2) forming a grid hole at a position corresponding to the light-emitting unit in the grid frame 51, where the grid hole at least exposes the light-emitting surface of the light-emitting unit, as shown in FIG. 22.
(3) forming the second reflective layer 52 at least on a side surface of the grid frame 51, as shown in FIG. 23.

Specifically, a material of the second reflective layer 52 may be a reflective material such as metal Al or Ag.

By disposing the grid frame 51 and the second reflective layer 52, an anti-crosstalk effect may be further enhanced.

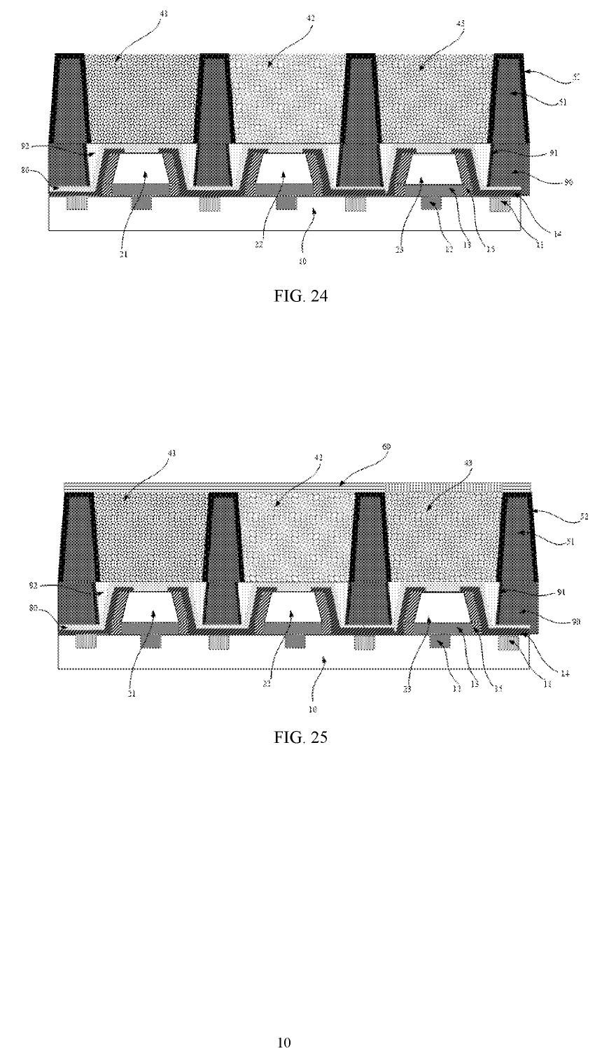

(4) forming first wavelength conversion units 41 and second wavelength conversion units 42 respectively in grid holes corresponding to the first light-emitting units 21 and the second light-emitting units 22, as shown in FIG. 24.

The first wavelength conversion unit 41 converts the light of the first color emitted by the first light-emitting unit 21 into the light of the second color, and the second wavelength conversion unit 42 converts the light of the first color emitted by the second light-emitting unit 22 into the light of the third color.

Optionally, S101 (forming the plurality of light-emitting units on the side of the driving circuit substrate) further includes following step:

(2) forming third light-emitting units 23 on the side of the driving circuit substrate, where light emitted by the third light-emitting units 23 and light emitted by the first light-emitting units 21 are of the same color, as shown in FIG. 22, that is, the third light-emitting unit 23 emits the light of the first color.

S104 (forming the color conversion layer above the plurality of light-emitting units) further includes following step:

(5) forming light-transmitting structures 43 in grid holes corresponding to the third light-emitting units 23, where the light-transmitting structures 43 are used for transmitting the light of the first color emitted by the third light-emitting units 23, as shown in FIG. 24.

In an embodiment of the present disclosure, after S104 (forming the color conversion layer above the plurality of light-emitting units, where the color conversion layer at least includes the first wavelength conversion units 41), the preparing method further includes following step:

forming a second transmissive-reflective layer 60 on the color conversion layer, where the second transmissive-reflective layer 60 is used for transmitting light of other color (such as the light of the second color) and reflect the light of the first color, as shown in FIG. 25.

Specifically, the second transmissive-reflective layer 60 includes at least five groups of film layers. Materials of two film layers in each group of film layers are any two materials selected from: TiO₂, SiO₂, SiNx, HfO₂, MgF₂, ZrO₂, and PMMA.

After the light of the second color emitted by the first wavelength conversion unit 41 passes through the second transmissive-reflective layer 60, the second transmissive-reflective layer 60 may further filter out the light of the first color that may be mixed in the light of the second color, improving the light emission purity of the sub-pixel region and enhancing color gamut of the overall display screen. At the same time, the second transmissive-reflective layer 60 reflects the light of the first color mixed in the light of the second color back into the first wavelength conversion unit 41, so that the light of the first color not converted by the first wavelength conversion unit 41 is absorbed and converted again by the first wavelength conversion unit 41, thereby improving the absorption and conversion capabilities of the wavelength conversion material in the wavelength conversion unit.

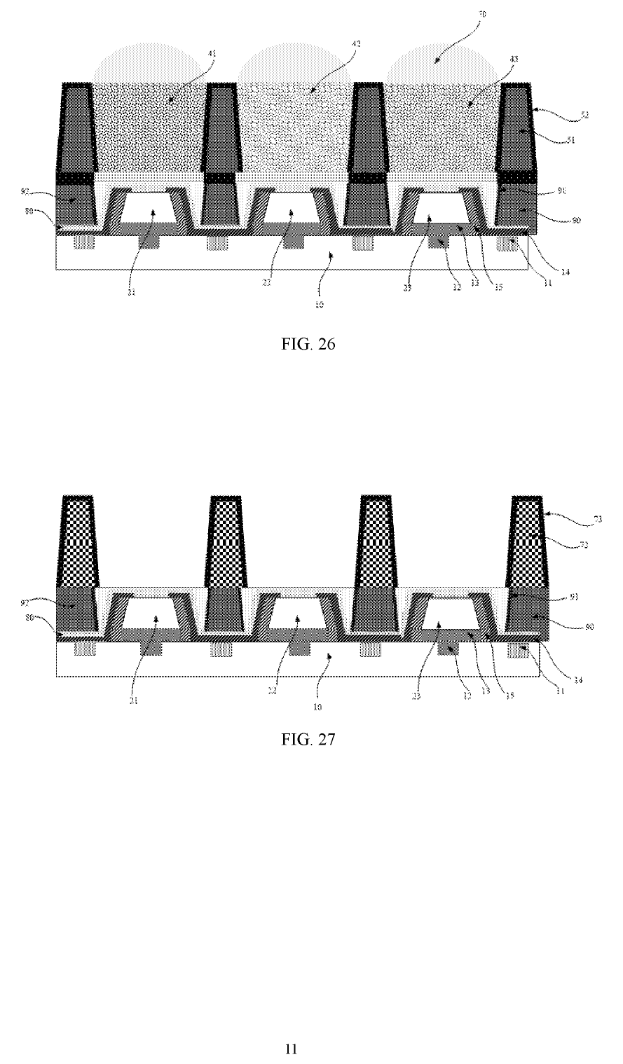

In an embodiment of the present disclosure, after S104 (forming the color conversion layer above the plurality of light-emitting units, where the color conversion layer at least includes the first wavelength conversion units 41), the preparing method further includes following step:
forming microlenses 70 above the plurality of light-emitting units, as shown in FIG. 26.

The microlenses 70 are disposed corresponding to the light-emitting units. The microlens 70 is used for converging or diverging light radiation. By disposing the microlens 70 in the embodiments of the present disclosure, a light emission angle may be reduced, thereby achieving convergence of converted light and enhancing a light emission effect.

In an embodiment of the present disclosure, after S103 (forming the first reflective layer 91 on the sidewall of the supporting unit 92) and before S104 (forming the color conversion layer above the plurality of light-emitting units), the preparing method further includes following steps:
forming a plurality of supporting structures 72 above the plurality of light-emitting units using a dam process, a gap existing between two adjacent supporting structures 72, and the gap corresponding to the light-emitting unit, as shown in FIG. 27; and
forming a third reflective layer 73 on a sidewall of the supporting structure 72.

The gap between two adjacent supporting structures 72 may be used for disposing a wavelength conversion unit or the light-transmitting structure 43. The third reflective layer 73 may further serve an anti-crosstalk function.

Forming the supporting structure 72 on the light-emitting unit using the dam process reduces process difficulty and improves efficiency.

The above descriptions are merely preferred embodiments of the present disclosure and are not intended to limit the present disclosure. Any modifications, equivalent replacements, or the like, made within the spirit and principles of the present disclosure shall be included within the protection scope of the present disclosure.

What is claimed is:

1. A micro-display chip structure, comprising:
a driving circuit substrate;
a plurality of light-emitting units disposed on the driving circuit substrate and spaced apart from each other, the plurality of light-emitting units at least comprising first light-emitting units, and the first light-emitting units being configured to emit light of a first color;
a color conversion layer disposed on the plurality of light-emitting units, the color conversion layer at least comprising first wavelength conversion units, the first wavelength conversion units being disposed corresponding to the first light-emitting units, and the first wavelength conversion units being configured to convert the light of the first color emitted by the first light-emitting units into light of a second color;
a supporting frame comprising a plurality of supporting units, each supporting unit of the plurality of supporting units being disposed corresponding to each light-emitting unit of the plurality of light-emitting units, and the supporting unit at least covering a sidewall of the light-emitting unit; and
a first reflective layer, at least covering a sidewall of the supporting unit.

2. The micro-display chip structure according to claim 1, wherein the supporting unit has an inclined sidewall.

3. The micro-display chip structure according to claim 1, further comprising:
a planarization layer filling a gap between two adjacent supporting units of the plurality of supporting units to form a flat top surface.

4. The micro-display chip structure according to claim 1, wherein the plurality of light-emitting units further comprise second light-emitting units, light emitted by the second light-emitting units and light emitted by the first light-emitting units are of the same color; and
the color conversion layer further comprises second wavelength conversion units, the second wavelength conversion units are disposed corresponding to the second light-emitting units, and the second wavelength conversion units are configured to convert light of the first color emitted by the second light-emitting units into light of a third color.

5. The micro-display chip structure according to claim 4, wherein the plurality of light-emitting units further comprise third light-emitting units, light emitted by the third light-emitting units and the light emitted by the first light-emitting units are of the same color; and
the color conversion layer further comprises light-transmitting structures, the light-transmitting structures are disposed corresponding to the third light-emitting units; and the light-transmitting structures are configured to transmit light of the first color emitted by the third light-emitting units.

6. The micro-display chip structure according to claim 1, further comprising:
a first transmissive-reflective layer disposed between the plurality of light-emitting units and the color conversion layer, wherein the first transmissive-reflective layer is configured to transmit the light of the first color and reflect light of other color.

7. The micro-display chip structure according to claim 6, wherein the first transmissive-reflective layer comprises:
a plurality of transmissive-reflective units, wherein the plurality of transmissive-reflective units are respectively disposed corresponding to the plurality of light-emitting units; and
a light-blocking structure, disposed between two adjacent transmissive-reflective units among the plurality of transmissive-reflective units;
wherein each transmissive-reflective unit of the plurality of transmissive-reflective units covers a light-emitting surface of a light-emitting unit disposed corresponding to the transmissive-reflective unit.

8. The micro-display chip structure according to claim 1, further comprising:
a thermal insulation layer disposed between the plurality of light-emitting units and the color conversion layer, wherein the thermal insulation layer is configured to at least transmit the light of the first color.

9. The micro-display chip structure according to claim 1, further comprising:
a second transmissive-reflective layer disposed above the color conversion layer, wherein the second transmissive-reflective layer is configured to transmit light of other color and reflect the light of the first color.

10. The micro-display chip structure according to claim 1, further comprising:
a plurality of microlenses disposed above the color conversion layer, wherein the plurality of microlenses are disposed corresponding to the plurality of light-emitting units.

11. A preparing method for a micro-display chip structure, comprising:
forming a plurality of light-emitting units on a side of a driving circuit substrate, the plurality of light-emitting units at least comprising first light-emitting units, and the first light-emitting units being configured to emit light of a first color under driving of the driving circuit substrate;
forming a supporting frame on the driving circuit substrate, the supporting frame comprising a plurality of supporting units, each supporting unit of the plurality of supporting units being disposed corresponding to each light-emitting unit of the plurality of light-emitting units, and the supporting unit at least covering a sidewall of the light-emitting unit;
forming a first reflective layer on a sidewall of the supporting unit; and
forming a color conversion layer above the plurality of light-emitting units, the color conversion layer at least comprising first wavelength conversion units, the first wavelength conversion units being disposed corresponding to the first light-emitting units, and the first wavelength conversion units being configured to convert the light of the first color emitted by the first light-emitting units into light of a second color.

12. The preparing method according to claim 11, wherein the forming the first reflective layer on the sidewall of the supporting unit comprises:
forming a reflective layer on the light-emitting unit, the reflective layer covering the sidewall and an upper surface of the supporting unit, a light-emitting surface of the light-emitting unit, and a gap between two adjacent light-emitting units of the plurality of light-emitting units; and
removing, by an etching process, the reflective layer on the upper surface of the supporting unit, the reflective layer on the light-emitting surface of the light-emitting unit, and the reflective layer in the gap between the two adjacent light-emitting units, and at least retaining the reflective layer located on the sidewall of the supporting unit;
wherein the first reflective layer is the reflective layer at least located on the sidewall of the supporting unit.

13. The preparing method according to claim 11, wherein after forming the first reflective layer on the sidewall of the supporting unit and before forming the color conversion layer above the plurality of light-emitting units, the preparing method further comprises:
forming a planarization layer on the driving circuit substrate, the planarization layer filling a gap between two adjacent supporting units of the plurality of supporting units to form a flat top surface;
wherein the forming the color conversion layer above the plurality of light-emitting units comprises:
forming the color conversion layer above the planarization layer,
wherein after forming the planarization layer on the driving circuit substrate and before forming the color conversion layer above the plurality of light-emitting units, the preparing method further comprises:
forming a first transmissive-reflective layer on the planarization layer, wherein the first transmissive-reflective layer is configured to transmit the light of the first color and reflect light of other color.

14. The preparing method according to claim 13, wherein the forming the first transmissive-reflective layer on the planarization layer comprises:
forming the first transmissive-reflective layer on the planarization layer through an exposure and development process, wherein the first transmissive-reflective layer comprises a plurality of transmissive-reflective units, and the plurality of transmissive-reflective units are respectively disposed corresponding to the plurality of light-emitting units; and
forming a light-blocking structure, disposed between two adjacent transmissive-reflective units of the plurality of transmissive-reflective units;
wherein each transmissive-reflective unit of the plurality of transmissive-reflective units covers a light-emitting surface of a light-emitting unit disposed corresponding to the transmissive-reflective unit.

15. The preparing method according to claim 11, wherein before forming the color conversion layer above the plurality of light-emitting units, the preparing method further comprises:
forming a thermal insulation layer on the plurality of light-emitting units;
wherein the forming the color conversion layer above the plurality of light-emitting units comprises: forming the color conversion layer above the thermal insulation layer.

16. The preparing method according to claim 11, wherein the forming the plurality of light-emitting units on the side of the driving circuit substrate comprises: forming the first light-emitting units and second light-emitting units on the side of the driving circuit substrate, the first light-emitting units and the second light-emitting units being configured to emit the light of the first color under driving of the driving circuit substrate,
wherein the forming the color conversion layer above the plurality of light-emitting units comprises:
forming a grid frame on the light-emitting unit;
forming a grid hole at a position corresponding to the light-emitting unit in the grid frame, the grid hole at least exposing a light-emitting surface of the light-emitting unit;
forming a second reflective layer at least on a side surface of the grid frame; and
forming the first wavelength conversion units and second wavelength conversion units respectively in grid holes corresponding to the first light-emitting units and the second light-emitting units.

17. The preparing method according to claim 16, wherein the forming the plurality of light-emitting units on the side of the driving circuit substrate further comprises: forming third light-emitting units on the side of the driving circuit substrate, wherein light emitted by the third light-emitting units and light emitted by the first light-emitting units are of the same color;
wherein the forming the color conversion layer above the plurality of light-emitting units further comprises:
forming light-transmitting structures in grid holes corresponding to the third light-emitting units, wherein the light-transmitting structures are configured to transmit the light of the first color emitted by the third light-emitting units.

18. The preparing method according to claim 11, further comprising:
forming a second transmissive-reflective layer on the color conversion layer, wherein the second transmissive-reflective layer is configured to transmit light of other color and reflect the light of the first color.

19. The preparing method according to claim 11, further comprising:
forming microlenses above the plurality of light-emitting units.

20. The preparing method according to claim 11, wherein after forming the first reflective layer on the sidewall of the supporting unit and before forming the color conversion layer above the plurality of light-emitting units, the preparing method further comprises:
forming a plurality of supporting structures above the plurality of light-emitting units using a dam process, a gap existing between two adjacent supporting structures, and the gap corresponding to the light-emitting unit; and
forming a third reflective layer on a sidewall of each of the plurality of supporting structures.
